(19) United States
(12) Patent Application Publication
(10) Pub. No.: US 2009/0050471 A1
(43) Pub. Date: Feb. 26, 2009

(54) PROCESS OF FORMING AN ELECTRONIC DEVICE INCLUDING DEPOSITING LAYERS WITHIN OPENINGS

(75) Inventors: Robert J. Chiu, San Jose, CA (US); Connie Pin-Chin Wang, Mountain View, CA (US); Minh Van Ngo, Fremont, CA (US); Simon S. Chan, Saratoga, CA (US)

Correspondence Address: LARSON NEWMAN ABEL & POLANSKY, LLP, 5914 WEST COURTYARD DRIVE, SUITE 200, AUSTIN, TX, 78730, US

(73) Assignee: SPANSION LLC, Sunnyvale, CA (US)

(21) Appl. No.: 11/844,518

(22) Filed: Aug. 24, 2007

(51) Int. Cl. C23C 14/32

(52) U.S. Cl. 204/192.12

(57) ABSTRACT

A process of forming an electronic device can include depositing a first layer over a substrate and depositing a second layer over the first layer. In one embodiment, depositing the first layer is performed at a first alternating current (“AC”) power, and depositing the second layer is performed at a second AC power that is different from the first AC power. In another embodiment, the first layer is formed by a physical vapor deposition technique at a first power sufficient to remove the insulating layer using first metal ions, wherein the first layer includes an overhanging portion extending over the bottom of the opening. In a further embodiment, the second layer is formed by the physical vapor deposition technique using second metal ions and a second power sufficient to reduce a lateral dimension of the overhanging portion.

### BACKGROUND

1. Field of the Disclosure

The present disclosure relates to processes of forming electronic devices, and more particularly, to processes of forming electronic devices including depositing layers within openings.

2. Description of the Related Art

Electronic devices can include conductive layers that are deposited by physical vapor deposition, such as sputtering. Sputtering is commonly used in forming an adhesion layer, a barrier layer, or any combination thereof before forming a conductive metallic fill material, such as tungsten or copper.

FIG. 1 includes an illustration of a cross-sectional view of a portion of a workpiece 10. The workpiece 10 can include a substrate 12 having electronic components formed within or over the substrate 12. The components can include gate structures, including a gate oxide layer 142 and gate electrodes 144 and 146, over the substrate 12. Sidewall spacers 148 lie beside the gate electrodes 144 and 146. The components further include source/drain regions 122, 124, and 126. An interlevel dielectric layer 160 is deposited over the gate structures and other portions of the substrate 12. The interlevel dielectric layer 160 can be patterned to form a contact opening 162. After formation of the contact opening 162, the workpiece 10 may be exposed to ambient air, and a native oxide layer 164 may be formed along the bottom of the contact opening 162.

One or more layers may be sputtered over the interlevel dielectric layer 160 and width in the contact opening 162. The native oxide 164 may remain or be consumed by a silicide reaction; however, the contact resistance within the contact opening 162 may be unacceptably high due to the presence of the native oxide 164 or residual portions thereof that may be incorporated into a metal silicide compound formed along the bottom of the contact opening 162. Thus, leaving the native oxide 164 is undesirable.

One prior art technique includes an argon backsputtering technique to remove the native oxide 164. In theory, the argon backsputtering is to remove substantially all of the native oxide layer 164. More particularly, the workpiece 10 can be placed into a sputtering tool and an ionized argon plasma can be directed towards the workpiece 10. The argon ions may physically remove the native oxide layer 164.

After the argon backsputtering is performed, a layer may be deposited over the interlevel dielectric layer 160 and within the contact opening 162. FIG. 2 includes a schematic diagram of a portion of a sputtering tool 20 when depositing the layer onto the workpiece 10. The sputtering tool includes a target 22 that includes material that is to be deposited onto the workpiece 10. The target 22 is coupled to a direct current (“DC”) power source. The workpiece 10 is held in place by a chuck 24 that is coupled to an alternating current (“AC”) power source. The circles 26 depict ions that include material from the target 22 as the ions travel towards the workpiece 10.

In one prior art technique, a single layer of material that has a composition substantially identical to the target 22 is deposited. In this embodiment, the DC power and the AC power are substantially constant during all of the deposition of the single layer. Another prior art technique includes depositing more than one layer, such as layers 302 and 304 over the workpiece 10, as illustrated in FIG. 3. The layers 302 and 304 can have substantially the same composition. In one particular prior art technique, a relatively low DC power is used at the target 22 to deposit the material relatively slower to form the layer 302. The DC power can be increased to accelerate the deposition rate such that the material is deposited at a faster rate for the layer 304, as compared to the layer 302.

In still another particular prior art technique, different DC power levels can be used at the target 22 to achieve reactive sputtering. For example, during a first relatively lower power pulse, a metal oxide film (not illustrated in FIG. 2) can be formed along the surface of the target 22. During a second relatively higher DC power pulse, the metal oxide film can be sputtered from the target 22 and deposited onto the workpiece 10. Referring to FIG. 3, the layer 302 may be formed during a first cycle of the low and high DC power pulses, and the layer 304 can be formed by a different cycle of the low and high DC power pulses. Additional layers can be formed but are not illustrated in FIG. 3. Regardless whether a single layer or more than one layer of substantially the same composition is being formed, the AC power remains substantially constant during portions of the cycle in which material is being deposited onto the workpiece 10. Changes to the power supply coupled to the target affects conditions at the target (e.g., removal rate, reaction of species at the surface of the target, etc.) and do not significantly affect the electrical field at locations spaced apart from the target.

### BRIEF DESCRIPTION OF THE DRAWINGS

The present disclosure may be better understood, and its numerous features and advantages made apparent to those skilled in the art by referencing the accompanying drawings.

FIG. 1 includes an illustration of a cross-sectional view of a workpiece including a substrate, transistors, a dielectric layer, and an opening through the dielectric layer and extending to a source/drain region. (Prior art)

FIG. 2 includes a schematic diagram of a sputtering tool including a target, a chuck the workpiece of FIG. 1, and power sources during a sputtering process. (Prior art)

FIG. 3 includes an illustration of a cross-sectional view of the workpiece of FIG. 1 after forming layers by a conventional process using the sputtering tool in FIG. 2. (Prior art.

FIG. 4 includes an illustration of a cross-sectional view of a workpiece after forming a plurality of layers over a substrate.

FIG. 5 includes an illustration of a cross-sectional view of the workpiece of FIG. 4 after patterning a layer to form gate electrodes.

FIG. 6 includes an illustration of a cross-sectional view of the workpiece of FIG. 5 after forming source/drain regions and spacers.

FIG. 7 includes an illustration of a cross-sectional view of the workpiece of FIG. 6 after a dielectric layer over the gate electrodes and source/drain regions.

FIG. 8 includes an illustration of a cross-sectional view of the workpiece of FIG. 7 after patterning the dielectric layer to form an opening.

FIG. 9 includes an illustration of a cross-sectional view of the workpiece of FIG. 8 after forming a first layer over the dielectric layer and within the opening.

FIG. 10 includes an illustration of a cross-sectional view of the workpiece of FIG. 9 after forming a second layer over the first layer.

FIG. 11 includes an illustration of a cross-sectional view of the workpiece of FIG. 10 after forming a third layer over the second layer.

FIG. 12 includes an illustration of a cross-sectional view of the workpiece of FIG. 11 after forming a conductive layer over the third layer.

FIG. 13 includes an illustration of a cross-sectional view of the workpiece of FIG. 12 after removing portions of the first, second, third, and conductive layer that lie over the dielectric layer and outside the opening to form a conductive structure within the opening.

FIG. 14 includes an illustration of a cross-sectional view of the workpiece of FIG. 13 after forming another dielectric layer over the dielectric layer and the conductive structure.

FIG. 15 includes an illustration of a cross-sectional view of the workpiece of FIG. 14 after forming an interconnect.

FIG. 16 includes an illustration of a cross-sectional view of the workpiece of FIG. 15 after forming a substantially completed electronic device.

FIG. 17 includes an illustration of a cross sectional view of a system wherein a processor is coupled to a display and an electronic device formed by a process described herein.

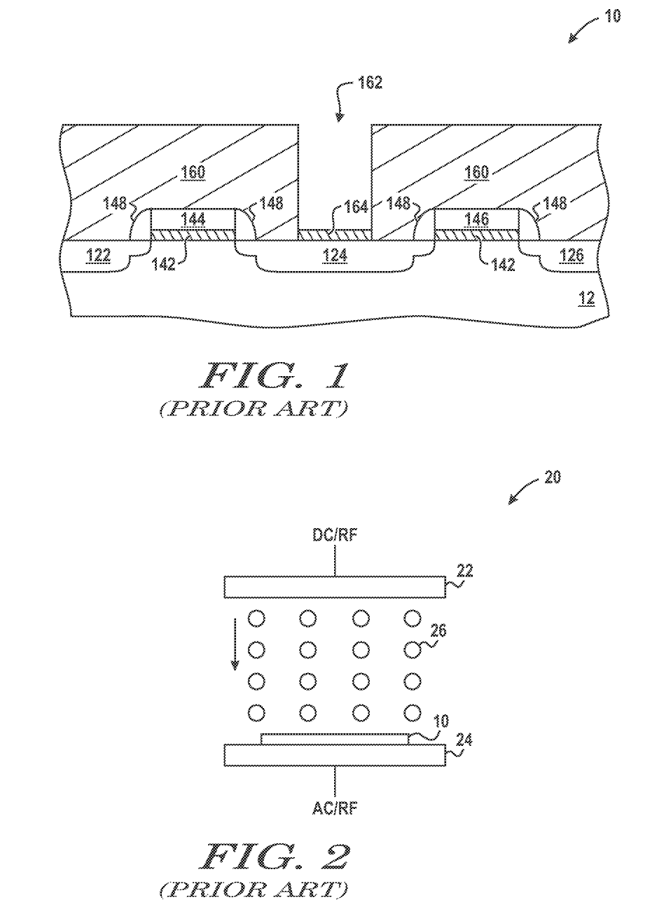

Skilled artisans appreciate that elements in the figures are illustrated for simplicity and clarity and have not necessarily been drawn to scale. For example, the dimensions of some of the elements in the figures may be exaggerated relative to other elements to help to improve understanding of embodiments of the invention.

### DETAILED DESCRIPTION

Electronic devices can include very high densities of components. In one particular embodiment, a memory array can include densely packed components, some of which can have features stacked one over another. Currently, electronic devices with memory cells are typically designed having design rules of no greater than 200 nm, and in many instances, the design rules are no greater than 65 nm. Contacts or other similar electrical connections to source/drain regions that lie within a substrate can be challenging to make due to the topology changes due to particular components or other features used in the electronic devices. Openings to the source/drain regions can have aspect ratios that can be relatively large. As used herein, an aspect ratio for an opening is the ratio of the depth of the opening to its width. Aspect ratios of at least 5:1 are becoming more common as the design rules for the electronic devices continue to shrink. An aspect ratio of approximately 7:1, approximately 10:1, or larger may be used in some electronic devices.

The inventors have discovered that conventional processing with such high aspect ratios can cause a problem in the proper formation of conductive structures that are to be formed within such deep, yet narrow openings. For example, an argon backsputter technique may no longer be acceptable to removing a native oxide or other insulating layer lying along a bottom of an opening. The argon backsputter can cause portions of a dielectric layer, through which the opening extends, to break off or otherwise be sputtered from the dielectric layer by the argon ions into the opening. Thus, in addition to a native oxide, portions of the dielectric layer can deposit along the bottom of the contact. This can make forming a contact with acceptable contact resistance even more difficult due to more oxide or other insulating materials lying along the bottom of the opening before forming a conductive layer within the opening.

In one aspect, a process of forming an electronic device can include depositing a first layer over a substrate, wherein depositing the first layer is performed at a first alternating current (“AC”) power. The process can also include depositing a second layer after depositing the first layer, wherein depositing the second layer is performed at a second AC power that is different from the first AC power. In a particular embodiment, the process can further include depositing a third layer after depositing the second layer, wherein depositing the third layer is performed at a third AC power that is between the first AC power and the second AC power. The first, second, and third layers can include a same metallic element, and more particularly, substantially the same composition. The first, second, and third layers can include nearly any material that can be sputtered, and in a particular embodiment, the first, second, and third layers can include a refractory metal element.

In another aspect, a process for forming an electronic device can include forming a first layer, wherein the first layer is formed by a physical vapor deposition technique at a first power sufficient to remove the insulating layer using first metal ions, wherein the first layer includes an overhanging portion extending over the bottom of the opening. In a particular embodiment, the process can also include forming a second layer, wherein the second layer is formed by the physical vapor deposition technique using second metal ions and a second power sufficient to reduce a lateral dimension of the overhanging portion. In a more particular embodiment, the process can include forming a third layer, wherein the third layer is formed by the physical vapor deposition technique using third metal ions and a third power, wherein the third power is between the first power and the second power.

By using an embodiment as described herein, the cumulative thickness of the deposited layers along the bottom of the opening can be at least 20% of the cumulative thickness of the deposited layers over a dielectric layer at a location spaced apart from the opening, even when the opening has an aspect ratio of at least 7:1. In another particular embodiment, the cumulative thickness along the bottom of the opening is typically at least approximately 35% of the cumulative thickness over the dielectric layer at the location spaced apart from the contact.

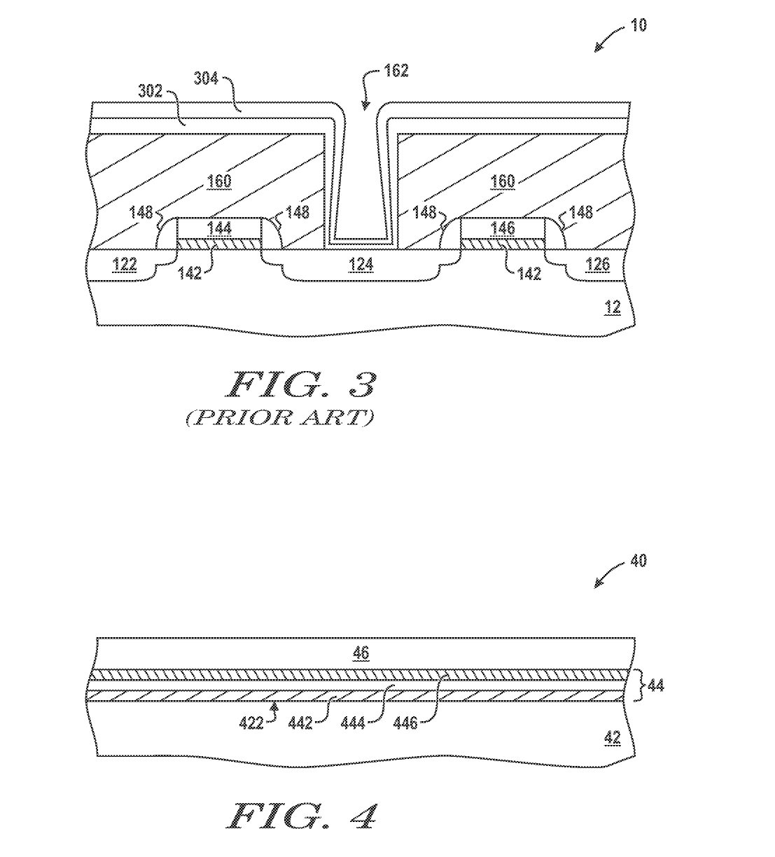

Attention is now directed to particular embodiments of forming an electronic device, as illustrated in FIGS. 4 to 16. FIG. 4 includes a cross-sectional view of a portion of a workpiece 40 after forming layers used in memory cells. In the embodiment as illustrated in FIG. 4, the memory cells are nonvolatile memory (“NVM”) cells. In other embodiments, other types of memory cells can be formed, such as dynamic random access memory (“DRAM”) cells, static random access memory (“SRAM”) cells, magnetoelectric random access memory (“MRAM”) cells, or the like.

The workpiece 40 includes a substrate 42 having a primary surface 422. The substrate 42 can include a monocrystalline semiconductor wafer, a semiconductor-on-insulator wafer, a flat panel display (e.g., a silicon layer over a glass electroplate), or other substrate conventionally used to form electronic devices. A charge storage stack 44 is formed over the substrate 42. The charge storage stack 44 can include an oxide layer 442, a charge storage layer 444, and another oxide layer 446. In one particular embodiment, the charge storage layer 444 can include a nitride layer, a doped silicon layer, or another suitable layer capable of storing a charge. In the particular embodiment as illustrated in FIG. 4, the charge storage layer 444 includes a nitride layer. A conductive layer 46 is formed over the charge storage stack 44. The conductive layer 46 can include doped silicon, a metal, a metal nitride, another suitable gate electrode material, or any combination thereof. The compositions, thicknesses, and formation techniques used in forming the charge storage stack 44 and the conductive layer 46 can be conventional or proprietary.

FIG. 5 includes an illustration of a cross-sectional view of the workpiece 40 after forming gate electrodes 52 and 54 from the conductive layer 46. In a particular embodiment, the gate electrodes 52 and 54 are parts of different word lines for memory cells within the memory array. The gate electrodes 52 and 54 can be formed by patterning the conductive layer 46 using a conventional or proprietary technique. The charge storage stack 44 may or may not be patterned during or after formation of the gate electrodes 52 and 54.

FIG. 6 includes an illustration of a cross-sectional view of the workpiece 40 after forming source/drain regions 622, 624, and 626 and spacers 64 adjacent to the sides of the gate electrodes 52 and 54. Formation of the source/drain regions 622, 624, and 626 and the spacers 64 can vary depending on the particular device characteristics to be achieved. For example, a relatively lighter dose of ions may be implanted into the substrate 42 before forming the spacers 64. After forming the spacers 64, a relatively heavier dose can be implanted into the substrate 42. An anneal cycle can be performed to activate the dopant from the ion implantations to form the source/drain regions 622, 624, and 626. The source/drain region 624 is a common source/drain region for the memory cells illustrated in FIG. 6.

The spacers 64 may be formed from a single layer or may be formed from a plurality of layers. For example, an oxide layer can be formed by thermally oxidizing a portion of the gate electrodes 52 and 54 or can be formed by depositing an oxide layer over the charge storage stack 44 and along the exposed surfaces of the gate electrodes 52 and 54. A nitride layer can then be deposited and etched to form the spacers 64. The spacers 64 may have a parabolic shape as illustrated in FIG. 6 or may have a relatively rectilinear shape or have another cross-sectional shape (not illustrated). The spacers 64 can formed using a conventional or proprietary technique. Portions of the gate electrodes 52 and 54 and regions within the substrate can be silicided if desired. The silicide can include TiSi₂, TaSi₂, CoSi₂, or the like. The silicidation can be performed using a conventional or proprietary technique.

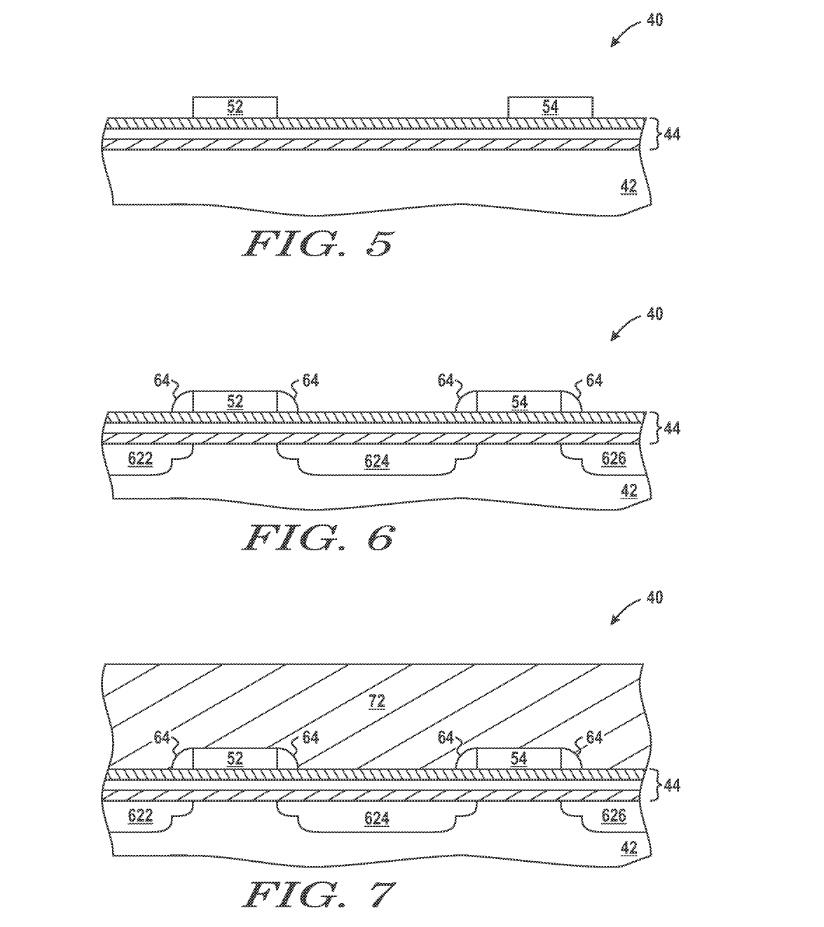

FIG. 7 includes a cross-sectional view of a portion of the workpiece 40 after forming a dielectric layer 72 over the gate electrodes 52 and 54 and the charge storage stack 44. In one embodiment, the dielectric layer 72 is an interlevel dielectric layer. The dielectric layer 72 can include a single film or a plurality of films. For example, the dielectric layer 72 can include an etch-stop film, an oxide film, and a polish-stop film. In another embodiment, more or fewer films may be present within the dielectric layer 72. In one embodiment, the dielectric layer 72 can have a thickness of at least 400 nm, at least 700 nm, or thicker, and in another embodiment, the thickness may be no greater than 2000 nm, no greater than 1000 nm, or thinner. The dielectric layer 72 can be formed using a conventional or proprietary deposition technique.

FIG. 8 includes an illustration of a cross-sectional view of the workpiece 40 after forming an opening 862 that extends through the dielectric layer 72 and after forming an insulating layer 864 along the bottom of the opening 862. In one embodiment, a resist or other masking layer (not illustrated) can be formed over the dielectric layer 72, wherein the resist layer includes an opening over a portion of the source/drain regions 624. An etching chemistry suitable to etch an opening in the dielectric layer 72 can be used. For example, a fluorine-based etching chemistry can be used to etch the opening 862 that extends through the dielectric layer 72 and the charge storage stack 44. After forming the opening 862, the resist layer is then removed. The workpiece 40 may then be exposed to an ambient that includes oxygen, such as molecular oxygen, water vapor, or the like, during or after the resist removal. In one particular embodiment, the exposure may be to room air within a fabricating area where the electronic device is being fabricated. Oxygen can react with a semiconductor material, such as silicon, that is exposed along the bottom of the opening 862. Thus, the insulating layer 864 can be a native oxide and may have a thickness no greater than 10 nm, and in another embodiment may have a thickness no greater than 8 nm. In still another embodiment the insulating layer 864 can have a thickness of at least 2 nm, and in another embodiment has a thickness of at least 6 nm. If the insulating layer 864 would not be removed, a highly resistive contact or an electrical open may result. Therefore, the insulating layer 864 will be at least partially or completely removed.

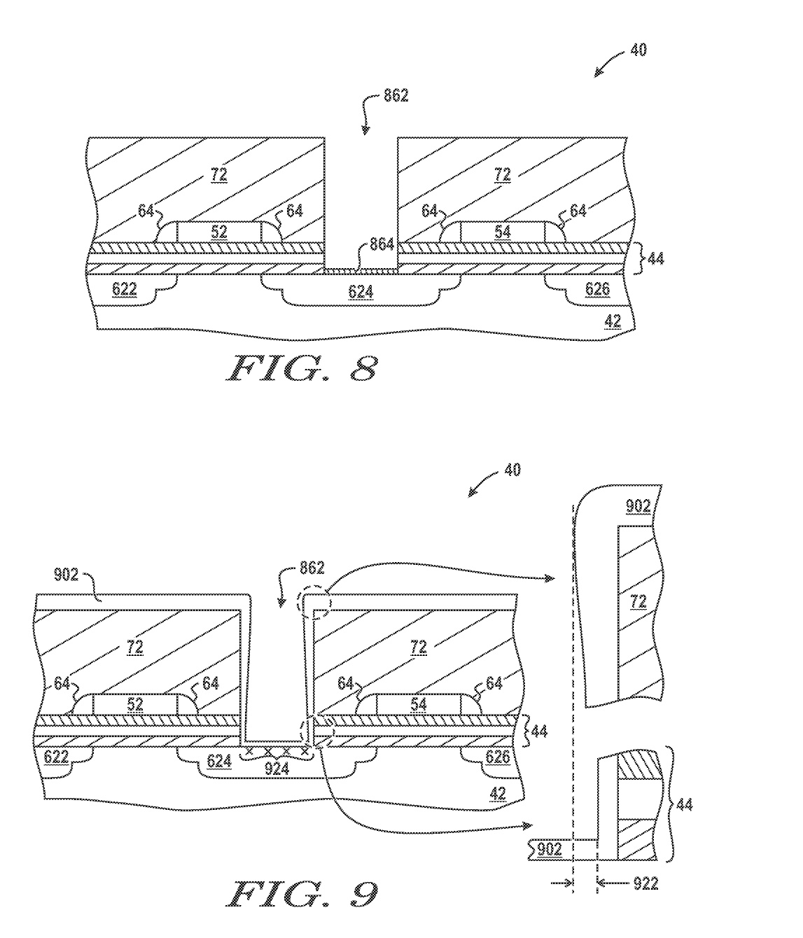

FIG. 9 includes an illustration of a cross-sectional view of the workpiece 40 after depositing a layer 902 over the dielectric layer 72 and within the opening 862. The workpiece 40 is placed onto a chuck or other substrate holder within a physical vapor deposition tool. In one particular embodiment, the physical vapor deposition tool includes a sputtering tool. The chuck or other substrate holder is electrically coupled to AC power. In one embodiment, the layer 902 can be deposited using a relatively higher AC power, as compared to a subsequent deposition. The relatively higher AC power allows ions from a target (not illustrated in FIG. 9) to be accelerated by a stronger electrical field adjacent to the surface of the workpiece 40. The relatively higher AC power increases the kinetic energy at which metal ions, originating from a target, reach the exposed surfaces of the workpiece 40. The actual AC power used may be affected by the size of the workpiece 40. For example, when the workpiece 40 or the substrate 42 has a nominal diameter of 200 mm, the power can be in a range of approximately 700 to approximately 1100 watts. In another embodiment, when the workpiece 40 or the substrate 42 has a nominal diameter of 300 mm, the AC power may need to be higher due to a larger surface area. After reading this specification, skilled artisans will the able to determine the actual power settings for the particular size of the workpiece or substrate used.

The material of the target can have heavier atoms as compared to the insulating layer 864. In a particular embodiment, the target can include a refractory metal element and have a melting point of at least 1400° C. An exemplary refractory metal element includes Ti, Ta, Mo, Co, W, or the like. Because the atoms from the target are heavier, the ions (charged atoms) can effectively sputter etch the insulating layer 864 away. In addition, some of the ions may be implanted into the source/drain region 624. Such implanted ions are depicted as a set of “X” labels 924 in FIG. 9. The implanted ions may allow a subsequently formed silicide layer to be formed more readily due to implant damage within the source/drain region 624.

During deposition of the layer 902, some of the layer 902 can accumulate near the upper corners of the dielectric layer and form an overhanging portion. As illustrated in FIG. 9, the overhanging portions in which, along a vertical axis (substantially perpendicular to the primary surface 422 (as illustrated in FIG. 4), a gap lies between (1) an upper portion of the layer 902 near the upper corner of the opening 862 and (2) a lower portion of the layer 902 lying along the bottom of the opening 862. In the embodiment as illustrated in FIG. 9, the overhanging portion of the layer 902 has a lateral dimension 922. As used herein, the lateral dimension is measured in a direction substantially parallel to the primary surface 422. The relatively high AC power deposition may be terminated before the lateral dimension 922 becomes too large.

Other than the AC power, all other deposition parameters for layer 902 can be conventional or proprietary. In one embodiment, the thickness of the layer 902 can be in a range of approximately 2.5 to approximately 3.5 nm.

FIG. 10 includes an illustration of a cross-sectional view of a portion of the workpiece 40 after depositing a layer 1002. The layer 1002 can be deposited using an AC power significantly less than the AC power used to form the layer 902. If the AC power is too low during deposition of the layer 1002, the overhanging portion formed when depositing layer 902 may not be knocked off when forming layer 1002. If the AC power is too high during deposition of the layer 1002, the lateral dimension of the overhanging may increase. Referring to FIG. 10, the lateral dimension of the overhanging portion of 902 and 1002 is reduced to a lateral dimension of 1022, which is significantly smaller than the lateral dimension 922. A portion of the layer 902 that is knocked off during the deposition of the layer 902 is part of the layer 1002 near the bottom corner of the opening 862 (not illustrated separately from the remainder of the layer 1002). In one particular embodiment, the AC power can be in a range of approximately 200 to approximately 400 watts for a workpiece 40 or the substrate 42 having a nominal diameter of 200 mm. Similar to layer 902, the AC power may need to be changed for different sizes of workpieces or substrates. In one embodiment, the thickness of the layer 1002 can be in a range of approximately 0.9 to approximately 2.0 nm.

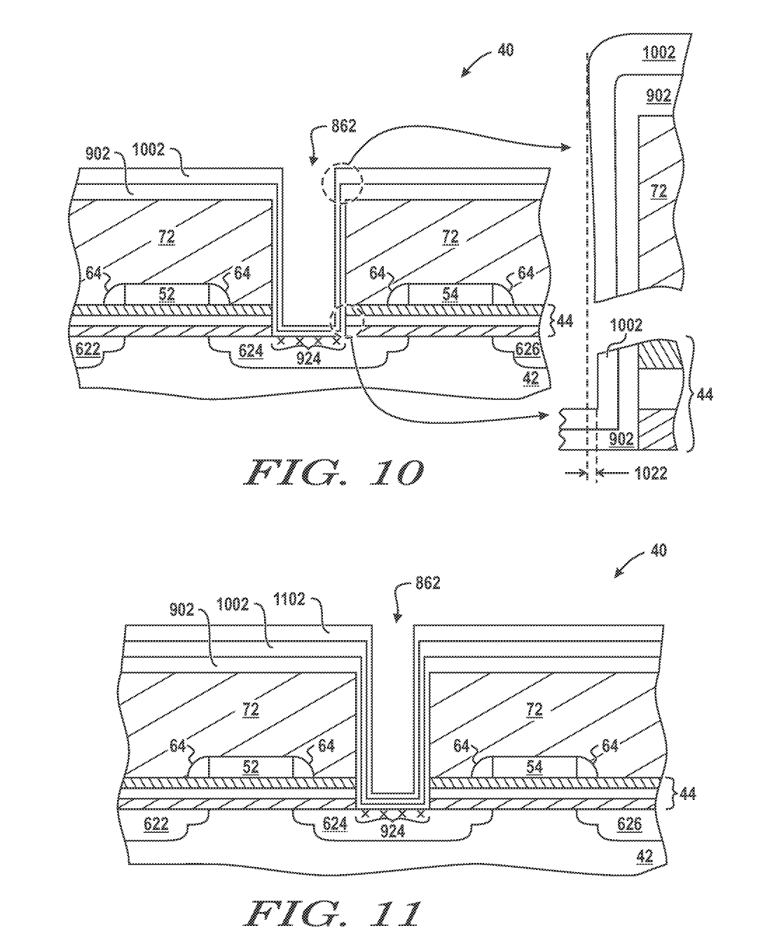

FIG. 11 includes an illustration of a cross-sectional view of the workpiece 40 after depositing the layer 1102. The layer 1102 can be deposited using in AC power between the values used to form the layers 902 and 1002. If the AC power is too low during depositing of the layer 1102, the thickness of the deposited material along the bottom of the opening 862 may be too thin. If the AC power is too high during deposition, the overhanging may form or increase too much during deposition of the layer 1102. In one particular embodiment, the AC power can be in a range of approximately 500 to approximately 900 watts when the workpiece 40 or the substrate 42 has a nominal diameter of 200 mm. Similar to the layer 902, the AC power may need to be changed for different sizes of workpieces or substrates. In one embodiment, the thickness of the layer 1102 can be in a range of approximately 0.5 to approximately 1.5 nm.

While the description has addressed the AC power used during deposition, other parameters may be held substantially constant or may be changed during or between depositing of the layers 902, 1002, and 1102. For example, the deposition rate can be affected by DC power at the target, or a substrate temperature can be changed which may affect the crystalline properties or lack thereof all of the layers formed. Thus, changing the other parameters may have no more than an insignificant impact on removal of the insulating layer 864, reducing the amount of lateral dimension of the overhanging portion within the opening 862, or allowing the material along the bottom of the opening 862 to become thicker. In a particular embodiment, the same target is used to form the layers 902, 1002, and 1102, and therefore the layers 902, 1002, and 1102 can have substantially the same composition.

By using a deposition process as described with respect to FIGS. 9 to 11, the thickness of material from the layers 902, 1002, and 1102 along the bottom of the opening 862 can be at least 20% of the thickness of the material from the layers 902, 1002, and 1102 formed over the dielectric layer 72 at a location spaced apart from the opening 862 (e.g., at least one micron away from the opening 862). In a more specific embodiment, the thickness of the material from the layers 902, 1002, and 1102 along the bottom can be at least 35% of the thickness of the material from the layers 902, 1002, and 1102 formed over the dielectric layer 72 at the location spaced apart from the opening 862. Therefore, a subsequently-formed silicide can be formed along the bottom of the opening 862 from the deposited material without consuming a significant portion of a subsequently-formed conductive material that will be deposited over the layers 902, 1002, and 1102.

A barrier layer (not illustrated) may be formed over the layer 1102 or from a portion of the layer 1102. The barrier layer can include a metal nitride or a metal-silicon-nitride compound (e.g., TiN, TaN, TaSiN, etc.). The thickness of the barrier layer is sufficient to act as a barrier to reduce the likelihood that a particular material on one side of the barrier layer will migrate to the other side of the barrier layer. If the barrier layer is too thick, the contact resistance may be too high. In one embodiment, the barrier layer is no greater than 30 nm, or no greater than 20 nm, and in another embodiment, the barrier layer is at least 5 nm, or at least 11 nm. The barrier layer can be formed using a conventional or proprietary technique. In another embodiment, the barrier layer may not be formed.

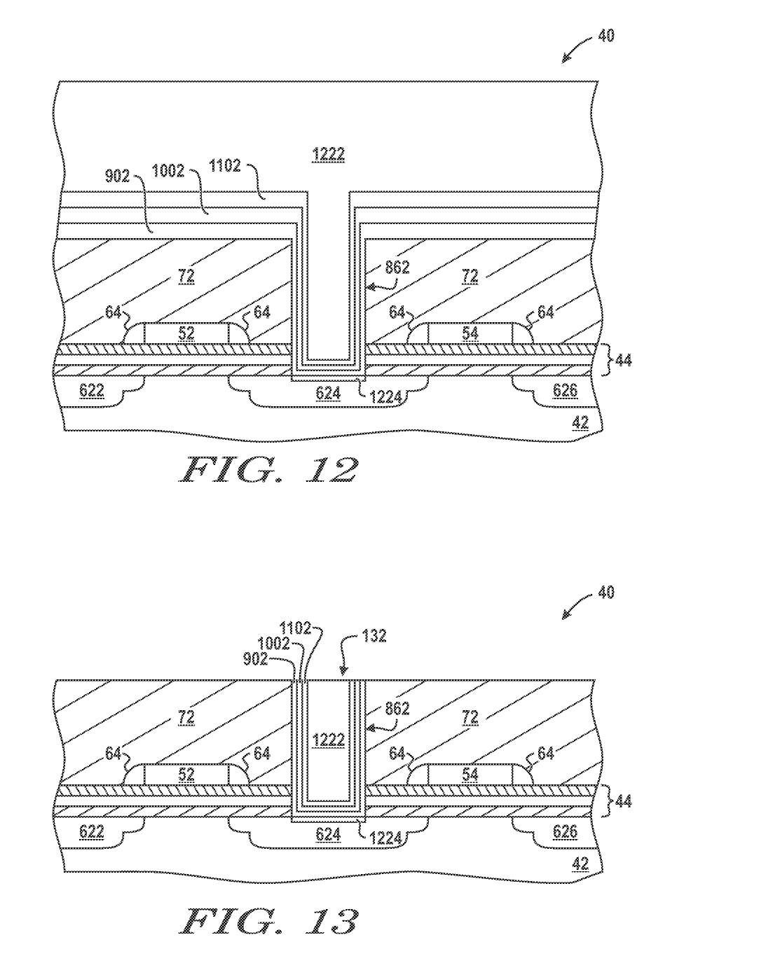

FIG. 12 includes an illustration of a cross-sectional view of the workpiece 40 after depositing a conductive layer 1222. The conductive layer 1222 is formed such that it substantially fills any remaining portion of the opening 862. In one particular embodiment, the conductive layer 1222 can be formed by a chemical vapor deposition that deposits a material more conformally as compared to the layer 902, 1002, or 1102. The material can include tungsten, polysilicon, or another material that is conductive or can be made conductive. The thickness of the conductive layer 1222 may be sufficiently thick such that an exposed surface of the conductive layer 1222 is substantially planar or has relatively small undulations corresponding to underlying topology variations, particularly over openings, such as the opening 862, other features, or any combination thereof. The conductive layer 1222 can be formed using a conventional or proprietary deposition technique.

In a particular embodiment, the implanted ions 924, a portion of the layer 902, 1002, 1102, or any combination thereof may react with a portion of a semiconductor material within the source/drain region 624 to form a metal-semiconductor compound 1224 during deposition of the conductive layer 1222. In a particular embodiment, the metal-semiconductor compound 1224 can be TiSi₂, TaSi₂, or the like, depending on the composition of the layer 902, 1002, 1102, or any combination thereof. After reading this specification, skilled artisans will appreciate that the metal-semiconductor compound 1224 may be formed before or after formation of the conductive layer 1222. For example, the metal-semiconductor compound 1224 can be formed during formation of the layer 1002 or 1102 or during an anneal after forming the layer 902, 1002, 1102, or the conductive layer 1222.

FIG. 13 includes an illustration of a cross-sectional view of the workpiece 40 after forming a conductive structure 132. In a particular embodiment, the conductive structure 132 includes a conductive plug, such as a contact plug. The conductive structure 132 can be formed by removing portions of the layers 902, 1002, and 1102 and the conductive layer 1222 that overlie the dielectric layer 72 outside of the opening 862. The portions of the layers 902, 1002, and 1102 and the conductive layer 1222 can be removed by conventional or proprietary polishing or etching techniques. In one particular embodiment, portions of the conductive layer 1222 and the layers 902, 1002, and 1102 can be removed by a substantially continuous chemically mechanical polishing action. In another particular embodiment, chemical mechanical polishing can be performed to remove portions of the conductive layer 1222 and stopping on the layer 1102, 1002, or 902 at locations over the dielectric layer 72 (not illustrated in FIG. 13). Portions of the layer 902, 1002, 1102, or any combination thereof can removed by polishing the layer 902, 1002, 1102, or any combination thereof using the same or different polishing parameters as used to remove portions of the conductive layer 1222. In another embodiment, portions of the layer 902, 1002, 1102, or any combination thereof can be removed by plasma etching using a conventional or proprietary technique.

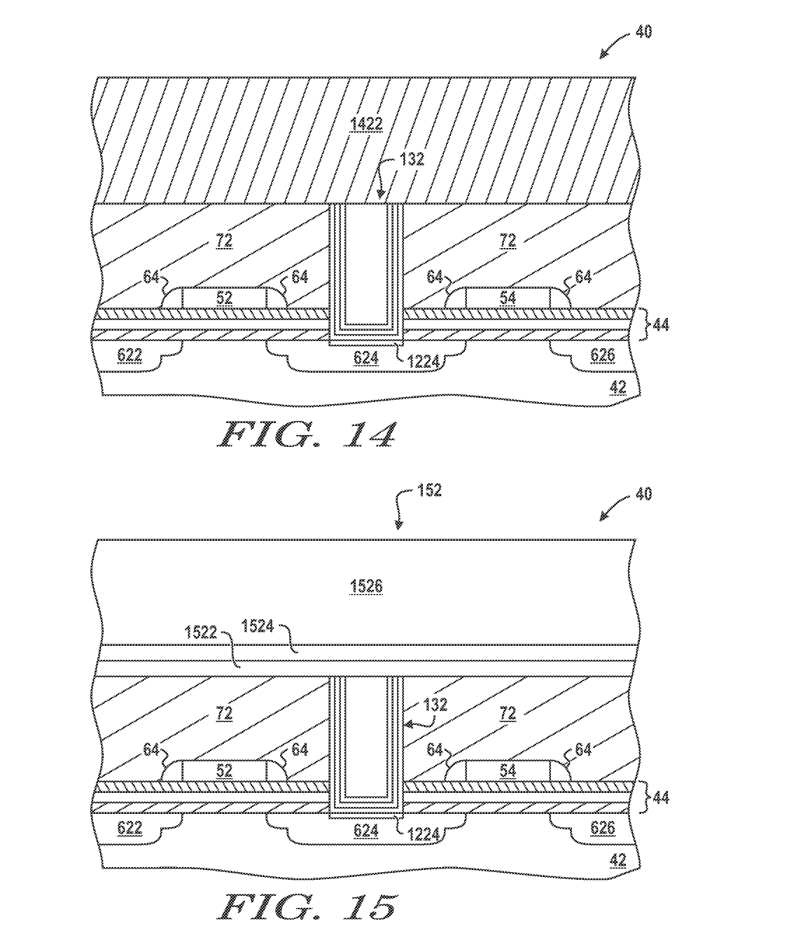

FIG. 14 includes an illustration of a cross-sectional view of the workpiece 40 after forming another dielectric layer 1422 over the dielectric layer 72 and the conductive structure 132. The dielectric layer 1422 may include a single insulating film or a plurality of insulating films. The dielectric layer 1422 can have any of the compositions, thicknesses, and use any of the formation techniques as described with respect to the dielectric layer 72. The composition, thickness, and formation of the dielectric layer 1422 can be the same or different as compared to the dielectric layer 72.

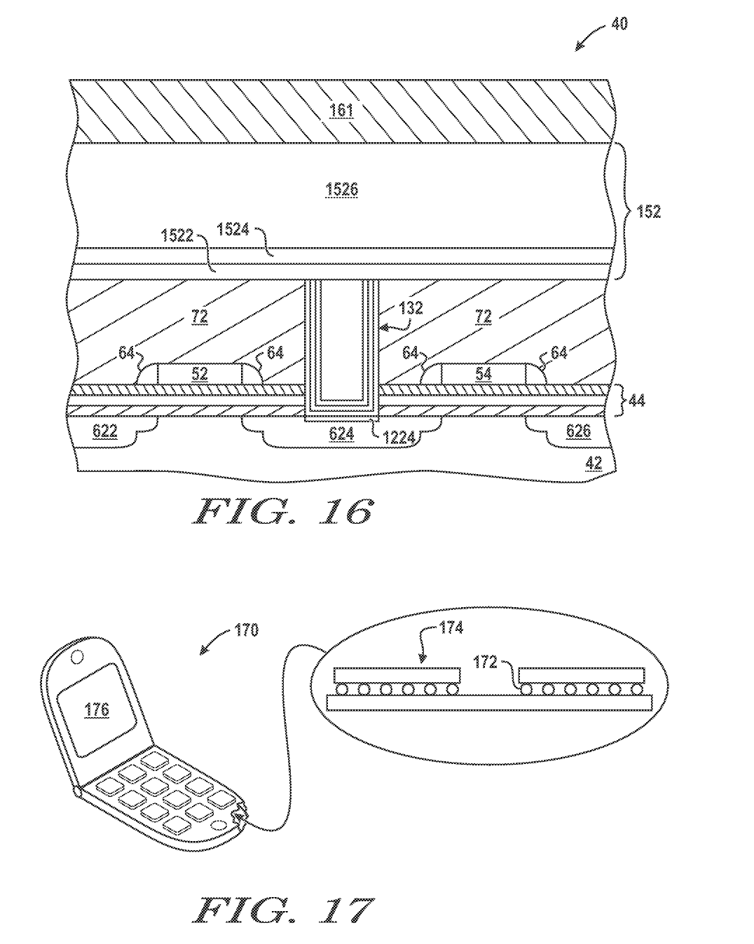

FIG. 15 includes an illustration of a cross-sectional view of the workpiece 40 after forming an interconnect 152 over the dielectric layer 72 and the conductive structure 132. The interconnect 152 allows electrical contact to being made to the source/drain region 624, and thus, the interconnect 152 can be a bit line for the memory cells illustrated in this particular embodiment. Although not illustrated, other contact openings can be formed to the gate electrodes 52 and 54 and to the source/drain regions 622 and 624. Gate electrodes 52 and 54 can be word lines, and the source/drain regions 622 and 624 can be electrically connected to other bit lines or may be part of a virtual grounding plane.

In one embodiment, a resist layer (not illustrated) can be formed over the dielectric layer 1422. The resist layer has openings corresponding to locations where interconnect trenches are to be formed. The dielectric layer 1422 can be etched using an etching chemistry suitable to etch an interconnect trench in the dielectric layer 1422. For example, fluorine-based etching chemistry can be used to form the interconnect trenches using a conventional or proprietary technique. Although not shown in FIG. 15, portions of the dielectric layer 1422 remain and separate the subsequently-formed interconnects from one another.

One or more conductive layers may be formed over remaining portions of the dielectric layer 1422 and within the interconnect trenches. In one embodiment, a barrier layer 1522 is formed over the dielectric layer 1422 and within the interconnect trenches. The barrier layer can include a metal nitride or a metal-silicon-nitride compound (e.g., TiN, TaN, TaSiN, etc.). The thickness of the barrier layer 1522 is sufficient to act as a barrier to reduce the likelihood that a particular material on one side of the barrier layer 1522 will migrate to the other side of the barrier layer. If the barrier layer 1522 is too thick, the contact resistance may be too high. In one embodiment, the barrier layer 1522 is no greater than 30 nm, or no greater than 20 nm, and in another embodiment, the barrier layer is at least 5 nm, or at least 11 nm. The barrier layer 1522 can be formed using a conventional or proprietary technique. In another embodiment, the barrier layer may not be formed. In another embodiment, an adhesion layer (not illustrated) can be formed before forming the barrier layer 1522 to improve adhesion between the barrier layer 1522 and the dielectric layers 72 and 1422.

A seed layer 1524 can be formed over the barrier layer 1522. The seed layer 1524 can be used to promote plating during a subsequent plating operation. In one embodiment, the seed layer 1524 can have substantially the same composition as the plated layer 1526. For example, the seed layer 1524 can include copper when copper is to be plated. In a particular embodiment, the seed layer 1524 can be formed using a conventional physical vapor deposition technique.

A plated layer 1526 can be formed by a plating a material onto the seed layer 1524. In a particular embodiment, the plated layer 1526 can include a noble metal, such as copper, silver, gold, or the like. The thickness of the plated layer 1526 is sufficient to at least fill the remaining portions of the interconnect trenches. In one embodiment, the plated layer 1526 can be electroplated using a conventional or proprietary electroplating technique.

Portions of the barrier layer 1522, the seed layer 1524, and the plated layer 1526 can be removed using one or more conventional or proprietary polishing or etching techniques. In one particular embodiment, the plated layer 1526 and the seed layer 1524 can be removed by chemical mechanical polishing the seed layer 1524 and the plated layer 1526 and stopping on the barrier layer 1522 at locations over the dielectric layer 1422 (not illustrated in FIG. 15). The barrier layer 1522 can be removed by polishing the barrier layer 1522 using the same or different polishing parameters as used to remove portions of the seed layer 1524 and the plated layer 1526. In another embodiment, the barrier layer 1522 can be removed by plasma etching using a conventional or proprietary technique.

FIG. 16 includes an illustration of a cross-sectional view of the workpiece 40 after forming a substantially completed electronic device. Although not illustrated additional dielectric layers and interconnect levels may be formed. After forming all of the dielectric layers and interconnect levels, an encapsulating layer 161 is then formed over the interconnects, including the interconnect 1526. The encapsulating layer 161 can include a single film or a plurality of films. The encapsulating layer 161 can include a conventional or proprietary composition and be formed using a conventional or proprietary deposition technique.

FIG. 17 includes an illustration of a system 170. The system 170 includes the electronic device 172 formed by the process described herein. In one embodiment, the electronic device 172 can be an integrated circuit that includes memory cells, such as nonvolatile memory cells, random access memory cells, other suitable memory cells, or any combination thereof. The electronic device 172 can be part of a standalone memory integrated circuit or may be part of a different type of integrated circuit.

The system 176 also includes a processor 174 is coupled to a display 178 and the electronic device 172. The processor 174 can include a central processing unit, a graphical processing unit, another suitable processing unit, or any combination thereof. The processor 174 may be part of a microcontroller, a microprocessor, a digital signal processor, another suitable data processing integrated circuit or the like. The processor 174 and the electronic device 172 can be separate integrated circuits mounted on the same printed wiring board or different printed wiring boards. In another embodiment, the processor 174 and the electronic device 172 may reside within the same integrated circuit. In one specific embodiment, the processor 174 can read data from the electronic device 172 and render or otherwise provide information to be displayed on the display 176 of the system 170.

Other embodiments can be used. The AC power source coupled to the chuck or other substrate holder can be replaced by a DC power source. The DC power source can be operated at a higher power to achieve a higher electrical field and at a lower power to reduce the electrical field. The concepts herein may be extended to another physical vapor deposition, such as inductively coupled plasma physical vapor deposition.

The concepts described herein can also be extended to vias (between interconnect levels) and to interconnect levels.

Embodiments can be used for different types of memory cells. In addition to an NVM cell, the process can be used for a DRAM cell, an SRAM cell, or an MRAM cell. In a DRAM cell, a storage capacitor can be formed that overlies a portion of a gate electrode. In an SRAM cell, load components (transistors or resistors) are formed over portions of the driver transistors, pass transistors, or any combination thereof. In an MRAM cell, the magnetoresistive element is typically formed as a stack and can include many layers. Thus, memory cells typically have greater elevational changes as compared to a single layer of logic transistors. The embodiments described herein can be useful for many different types of memory cells.

Embodiments described herein can allow better step coverage of physical vapor deposited layer with relatively higher aspect ratios. For example, at one particular aspect ratio, a conventional method may produce one or more layers where the thickness or cumulative thickness of the layers over a bottom of an opening is only about 15 to 17 percent of the thickness or cumulative thickness of the layers over a dielectric layer away from the opening. Using an embodiment described herein, the fraction can be more that 20 percent, more than 30 percent, more than 35 percent, or potentially higher. A subsequently conductive layer will be less likely to react with an underlying region that includes a semiconductor material (e.g., a source/drain region, a gate electrode, etc.).

Further, the overhanging portion of the layer or layers can be reduced, thus, allowing more of a subsequent conductive layer to be formed within the opening and reducing the likelihood of forming a void within the opening. Thus, the contact resistance can be lowered.

The embodiments can be implemented using an existing physical vapor deposition tool, and therefore, does not require any capital investment. Additionally, the processes described herein can be implemented without any significant reduction in tool capacity. The processes may be implemented by changes in software (e.g., recipes). Some of the values of parameters can be scaled for different sizes of substrate.

Many different aspects and embodiments are possible. Some of those aspects and embodiments are described below. After reading this specification, skilled artisans will appreciate that those aspects and embodiments are only illustrative and do not limit the scope of the present invention.

In a first aspect, a process of forming an electronic device can include depositing a first layer over a substrate, wherein depositing the first layer is performed at a first AC power. The process can also include depositing a second layer after depositing the first layer, wherein depositing the second layer is performed at a second AC power that is different from the first AC power.

In one embodiment of the first aspect, the first layer and the second layer include a same metallic element. In another embodiment, the process further includes depositing a third layer after depositing the second layer, wherein depositing the third layer is performed at a third AC power that is between the first AC power and the second AC power. In a particular embodiment, the first layer, the second layer, and the third layer include substantially the same composition, and wherein the second layer lies between and contacts the first layer and the third layer. In another particular embodiment, depositing the first layer, depositing the second layer, and depositing the third layer are performed using a physical vapor deposition technique.

In still another particular embodiment of the first aspect, the process further includes forming a dielectric layer over the substrate before forming the first layer, patterning the dielectric layer to define an opening before forming the first layer, and forming an insulating layer along a bottom of the opening before forming the first layer. In a more particular embodiment, the insulating layer includes a native oxide. In another more particular embodiment, patterning the dielectric layer is performed such that the opening has an aspect ratio of at least 7:1. In still another more particular embodiment, the process further includes forming a memory cell before forming the dielectric layer. The memory cell includes a gate electrode and a source/drain region, and patterning the dielectric layer is performed such that the opening overlies the gate electrode or the source/drain region.

In a second aspect, a process of forming an electronic device can include forming a doped semiconductor region and forming a dielectric layer over the doped semiconductor region. The process can also include patterning the dielectric layer to define an opening extending to the doped semiconductor region and forming an insulating layer along a bottom of the opening and over the doped semiconductor region. The process can further include forming a first layer. The first layer can be formed by a physical vapor deposition technique at a first power sufficient, removing the insulating layer using first metal ions during forming the first layer, wherein the first layer includes an overhanging portion extending over the bottom of the opening.

In one embodiment of the second aspect, during forming the first layer, some of the first metal ions are implanted into the doped semiconductor region. In another embodiment, the process further includes forming a second layer, wherein the second layer is formed by the physical vapor deposition technique using second metal ions and a second power sufficient to reduce a lateral dimension of the overhanging portion. In a particular embodiment, the process further includes forming a third layer, wherein the third layer is formed by the physical vapor deposition technique using third metal ions and a third power, wherein the third power is between the first power and the second power. In still another embodiment, the process further includes forming a conductive layer, such that after forming the conductive layer, the opening is substantially filled with conductive materials and removing portions of the conductive layer and the first layer overlying the dielectric layer and outside the opening to form a conductive structure.

In a third aspect, a process of forming an electronic device can include forming a first memory cell and a second memory cell, wherein the first memory cell and the second memory cell share a common source/drain region, and forming a dielectric layer over the first memory cell and the second memory cell. The process can also include patterning the dielectric layer to define an opening extending to the common source/drain region and growing a native oxide from a portion of the common source/drain region. The process can further include physical vapor depositing a first layer over dielectric layer and within the opening, wherein depositing the first layer is performed using a source material and at a first alternating current (“AC”) power and using a source material, physical vapor depositing a second layer over the first layer and within the opening, wherein depositing the second layer using the source material and is performed at a second AC power that is different from the first AC power, and physical vapor depositing a third layer over the second layer, wherein depositing the third layer is performed using the source material and at a third AC power that is between the first AC power and the second AC power. The process can still further include forming a fourth layer over the third layer and within the opening, such that after forming the fourth layer, the opening is filled, wherein the fourth layer includes a different element as compared to the first layer, the second layer, and the third layer, and removing portions of the first layer, the second layer, the third layer, and the fourth layer to form a conductive structure.

In one embodiment of the third aspect, forming the first memory cell and the second memory cell is performed using a substrate having a nominal diameter of 200 mm. For that particular size of substrate, the first AC power is in a range of approximately 700 watts to approximately 1100 watts; the second AC power is in a range of approximately 200 watts to approximately 400 watts, and the third AC power is in a range of approximately 500 to 900 watts.

In another embodiment of the third aspect, patterning the dielectric layer is performed such that the opening has an aspect ratio of at least 7:1. In a particular embodiment, after depositing the third layer, a first cumulative thickness includes a sum of thicknesses of the first layer, the second layer, and the third layer along a bottom of the opening, a second cumulative thickness includes a sum of thicknesses of the first layer, the second layer, and the third layer over the dielectric layer and spaced apart from the opening, and the first cumulative thickness divided by the second cumulative thickness is at least 0.2. In a further embodiment, physical vapor depositing the first layer includes implanting ions including the source material into the common source/drain region.

Any of the processes as described herein can be used to form an electronic device that is part of a system. In one embodiment, a process of forming an electronic system can include providing a processor and providing the electronic device. The electronic device and the processor can be electrically coupled to each other. The process can also include electrically coupling the processor and a display component to each other.

Note that not all of the activities described above in the general description or the examples are required, that a portion of a specific activity may not be required, and that one or more further activities may be performed in addition to those described. Still further, the order in which activities are listed are not necessarily the order in which they are performed.

In the foregoing specification, the concepts have been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

After reading the specification, skilled artisans will appreciated that certain features are, for clarity, described herein in the context of separate embodiments, may also be provided in combination in a single embodiment. Conversely, various features that are, for brevity, described in the context of a single embodiment, may also be provided separately or in any subcombination. Further, references to values stated in ranges include each and every value within that range.

What is claimed is:

1. A process of forming an electronic device comprising:
depositing a first layer over a substrate, wherein depositing the first layer is performed at a first alternating current (“AC”) power; and
depositing a second layer after depositing the first layer, wherein depositing the second layer is performed at a second AC power that is different from the first AC power.

2. The process of claim 1, wherein the first layer and the second layer comprise a same metallic element.

3. The process of claim 1, further comprising depositing a third layer after depositing the second layer, wherein depositing the third layer is performed at a third AC power that is between the first AC power and the second AC power.

4. The process of claim 3, wherein the first layer, the second layer, and the third layer comprise substantially the same composition, and wherein the second layer lies between and contacts the first layer and the third layer.

5. The process of claim 3, wherein depositing the first layer, depositing the second layer, and depositing the third layer are performed using a physical vapor deposition technique.

6. The process of claim 3, further comprising:
forming a dielectric layer over the substrate before forming the first layer;
patterning the dielectric layer to define an opening before forming the first layer; and
forming an insulating layer along a bottom of the opening before forming the first layer.

7. The process of claim 6, wherein the insulating layer comprises a native oxide.

8. The process of claim 6, wherein patterning the dielectric layer is performed such that the opening has an aspect ratio of at least 7:1.

9. The process of claim 6, further comprising forming a memory cell before forming the dielectric layer, wherein:
the memory cell includes a gate electrode and a source/drain region; and
patterning the dielectric layer is performed such that the opening overlies the gate electrode or the source/drain region.

10. A process of forming an electronic system comprising:
providing a processor and an electronic device formed by the process of claim 1, wherein the electronic device and the processor are electrically coupled to each other; and
electrically coupling the processor and a display component to each other.

11. A process of forming an electronic device comprising:
forming a doped semiconductor region;
forming a dielectric layer over the doped semiconductor region;
patterning the dielectric layer to define an opening extending to the doped semiconductor region;
forming an insulating layer along a bottom of the opening and over the doped semiconductor region; and
forming a first layer, wherein the first layer is formed by a physical vapor deposition technique at a first power sufficient, removing the insulating layer using first metal ions during forming the first layer, wherein the first layer includes an overhanging portion extending over the bottom of the opening.

12. The process of claim 11, wherein during forming the first layer, some of the first metal ions are implanted into the doped semiconductor region.

13. The process of claim 11, further comprising forming a second layer, wherein the second layer is formed by the physical vapor deposition technique using second metal ions and a second power sufficient to reduce a lateral dimension of the overhanging portion.

14. The process of claim 13, further comprising forming a third layer, wherein the third layer is formed by the physical vapor deposition technique using third metal ions and a third power, wherein the third power is between the first power and the second power.

15. The process of claim 11, further comprising:
forming a conductive layer, such that after forming the conductive layer, the opening is substantially filled with conductive materials; and
removing portions of the conductive layer and the first layer overlying the dielectric layer and outside the opening to form a conductive structure.

16. A process of forming an electronic device comprising:
forming a first memory cell and a second memory cell, wherein the first memory cell and the second memory cell share a common source/drain region;
forming a dielectric layer over the first memory cell and the second memory cell;
patterning the dielectric layer to define an opening extending to the common source/drain region;
growing a native oxide from a portion of the common source/drain region;
physical vapor depositing a first layer over dielectric layer and within the opening, wherein depositing the first layer is performed using a source material and at a first alternating current (“AC”) power and using a source material;
physical vapor depositing a second layer over the first layer and within the opening, wherein depositing the second layer using the source material and is performed at a second AC power that is different from the first AC power;
physical vapor depositing a third layer over the second layer, wherein depositing the third layer is performed using the source material and at a third AC power that is between the first AC power and the second AC power;
forming a fourth layer over the third layer and within the opening, such that after forming the fourth layer, the opening is filled, wherein the fourth layer comprises a different element as compared to the first layer, the second layer, and the third layer; and
removing portions of the first layer, the second layer, the third layer, and the fourth layer to form a conductive structure.

17. The process of claim 16, wherein:
forming the first memory cell and the second memory cell is performed using a substrate having a nominal diameter of 200 mm;
the first AC power is in a range of approximately 700 watts to approximately 1100 watts;
the second AC power is in a range of approximately 200 watts to approximately 400 watts; and
the third AC power is in a range of approximately 500 to 900 watts.

18. The process of claim 16, wherein patterning the dielectric layer is performed such that the opening has an aspect ratio of at least 7:1.

19. The process of claim 18, wherein after depositing the third layer:
a first cumulative thickness comprises a sum of thicknesses of the first layer, the second layer, and the third layer along a bottom of the opening;
a second cumulative thickness comprises a sum of thicknesses of the first layer, the second layer, and the third layer over the dielectric layer and spaced apart from the opening; and
the first cumulative thickness divided by the second cumulative thickness is at least 0.2.

20. The process of claim 16, wherein physical vapor depositing the first layer comprises implanting ions comprising the source material into the common source/drain region.
